(19) United States
(12) Patent Application Publication
(10) Pub. No.: US 2014/0170533 A1
(43) Pub. Date: Jun. 19, 2014

(54) EXTREME ULTRAVIOLET LITHOGRAPHY (EUVL) ALTERNATING PHASE SHIFT MASK

(71) Applicants: GLOBAL FOUNDRIES INC., Grand Cayman (KY); SEMATECH, INC., Albany, NY (US)

(72) Inventors: Lei Sun, Albany, NY (US); Pawitter S. Mangat, Clifton Park, NY (US); Vibhu Jindal, Niskayuna, NY (US); Obert R. Wood, II, Loundonville, NY (US)

(73) Assignees: SEMATECH, INC., Albany, NY (US); GLOBALFOUNDRIES INC., Grand Cayman (KY)

(21) Appl. No.: 13/719,621

(22) Filed: Dec. 19, 2012

(51) Int. Cl. G03F 1/22

(52) U.S. Cl. CPC G03F 1/22
USPC 430/5

(57) ABSTRACT

An alternating phase shift mask for use with extreme ultraviolet lithography is provided. A substrate with a planar top surface is used as a base for the phase shift mask. A spacer layer serves as a Fabry-Perot cavity for controlling the phase shift difference between two adjacent surfaces of the phase shift mask and controlling the reflectivity from the top of the second multilayer. A protective layer serves as an etch stop layer to protect a first multilayer region in certain regions of the phase shift mask, while other regions of the phase shift mask utilize a second multilayer region for achieving a phase shift difference. Some embodiments may further include an absorber layer region to provide areas with no reflectance, in addition to the areas of alternating phase shift. Embodiments of the present invention may be used to monitor the focus and aberration of a lithography tool.

### FIELD OF THE INVENTION

The present invention relates generally to semiconductor fabrication, and more particularly, to an alternating phase shift mask for extreme ultraviolet lithography.

### BACKGROUND

Semiconductor devices are manufactured by depositing many different types of material layers over a semiconductor work piece or wafer and patterning the various material layers using lithography. The material layers typically comprise thin films of different materials that are patterned and etched to form integrated circuits (ICs).

In the semiconductor industry, optical lithography techniques such as contact printing, proximity printing, and projection printing have been used to pattern material layers of integrated circuits. However, as the minimum feature sizes of ICs are decreased, the semiconductor industry is trending towards the use of very short wavelengths to achieve the decreased feature sizes demanded by the industry.

For lithographic printing of integrated circuit patterns below about 40 nanometers feature sizes, extreme ultraviolet lithography (EUVL) technology using light with a wavelength of less than 15 nanometers is a viable process. Ultraviolet (UV) light has a shorter wavelength than visible light. For example, UV light is usually considered to fall within the wavelength range of about 157 to 400 nanometers. In EUVL, extreme UV (EUV) light, having a shorter wavelength than UV light (e.g., about 13.5 nanometers), is used as the wavelength.

There are several advanced techniques for forming reticles that allow more aggressive imaging resolution capabilities. These include phase shift masks (PSMs) where the area surrounding the mask feature to be imaged are shifted in phase so as to interfere with the adjacent image from the pattern and create a smaller feature at the wafer surface. A phase shift mask (PSM) can dramatically enhance the image contrast. However, fabricating a phase shift mask for EUV applications can be challenging, as there are various factors that can reduce the precision and accuracy of such masks. It is therefore desirable to have an improved phase shift mask and method of fabrication.

### SUMMARY OF THE INVENTION

In general, embodiments of the invention provide an improved alternating phase shift mask for use with extreme ultraviolet lithography. A substrate with a planar top surface is used as a base for the phase shift mask. A spacer layer serves as a Fabry-Perot cavity for controlling the phase shift difference between two adjacent surfaces of the phase shift mask and controlling the reflectivity from the top of the second multilayer. A protective layer serves as an etch stop layer to preserve a first multilayer region in certain regions of the phase shift mask, while other regions of the phase shift mask utilize a second multilayer region for achieving a phase shift difference. Some embodiments may further include an absorber layer region to provide areas with no reflectance, in addition to the areas of alternating phase shift. Embodiments of the present invention are used to monitor the focus and aberration of a lithography tool.

A first aspect of the present invention includes a phase shift mask, comprising: a substrate; a first multilayer region disposed on the substrate; a protective layer disposed on the first multilayer region; a spacer layer disposed on a first portion of the protective layer; and a second multilayer region disposed on the spacer layer, wherein a second portion of the protective layer is exposed.

A second aspect of the present invention includes a phase shift mask, comprising: a substrate; a first multilayer region disposed on the substrate; a first protective layer disposed on the first multilayer region; a spacer layer disposed on a first portion of the first protective layer; a second multilayer region disposed on the spacer layer, wherein a second portion of the first protective layer is exposed; a second protective layer disposed on the second multilayer region; and an absorber layer disposed on a first portion of the second protective layer, wherein a second portion of the second protective layer is exposed.

A third aspect of the present invention includes a method of fabricating a phase shift mask, comprising: forming a first multilayer region on a substrate; depositing a first protective layer on the first multilayer region; depositing a spacer layer on the first protective layer; forming a second multilayer region on the spacer layer; and removing a portion of the second multilayer region and spacer region.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity. Furthermore, for clarity, some reference numbers may be omitted in certain drawings.

Features of this invention will be more readily understood from the following detailed description of the various aspects of the invention taken in conjunction with the accompanying drawings in which:

FIG. 1 shows a structure in accordance with illustrative embodiments.

FIG. 2 shows a structure in accordance with illustrative embodiments after applying a mask.

FIG. 3 shows a structure in accordance with illustrative embodiments after an etch process.

FIG. 4 shows a structure in accordance with alternative illustrative embodiments.

FIG. 5 shows a structure in accordance with alternative illustrative embodiments after removal of a portion of the top multilayer.

FIG. 6 shows a structure in accordance with alternative illustrative embodiments after removal of a first mask.

FIG. 7 shows a structure in accordance with alternative illustrative embodiments after application of a second mask.

FIG. 8 shows a structure in accordance with alternative illustrative embodiments after removal of a portion of the absorber layer.

FIG. 9 is a flowchart showing process steps for illustrative embodiments.

FIG. 10 is a flowchart showing process steps for alternative illustrative embodiments.

### DETAILED DESCRIPTION

Exemplary embodiments will now be described more fully herein with reference to the accompanying drawings, in which exemplary embodiments are shown. Exemplary embodiments of the invention provide an improved alternating phase shift mask for use with extreme ultraviolet lithography. A substrate with a planar top surface is used as a base for the phase shift mask. A spacer layer serves as a Fabry-Perot cavity for controlling the phase shift difference between two adjacent surfaces of the phase shift mask and controlling the reflectivity from the top of the second multilayer. A protective layer serves as an etch stop layer to preserve a first multilayer region in certain regions of the phase shift mask, while other regions of the phase shift mask utilize a second multilayer region for achieving a phase shift difference and large reflectivity. Some embodiments may further include an absorber layer region, to provide areas with no reflectance, in addition to the areas of alternating phase shift. Embodiments of the phase shift mask exhibit reduced transition areas between the two regions of alternating phase within the mask. This enables the potential for smaller features on the end workpiece (e.g., wafer or die). Some embodiments further utilize an absorber layer, and are well suited for focus monitoring applications. Focus control is becoming more important in lithography as a result of Depth of Focus (DOF) shrinking. Although modern lithographic scanners have internal focus sensors, focus error can still arise from scanner assembly issues and maintenance, as well as geographical and environmental differences. Therefore, focus measurement methods providing an independent test of the on-board metrology are desirable.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

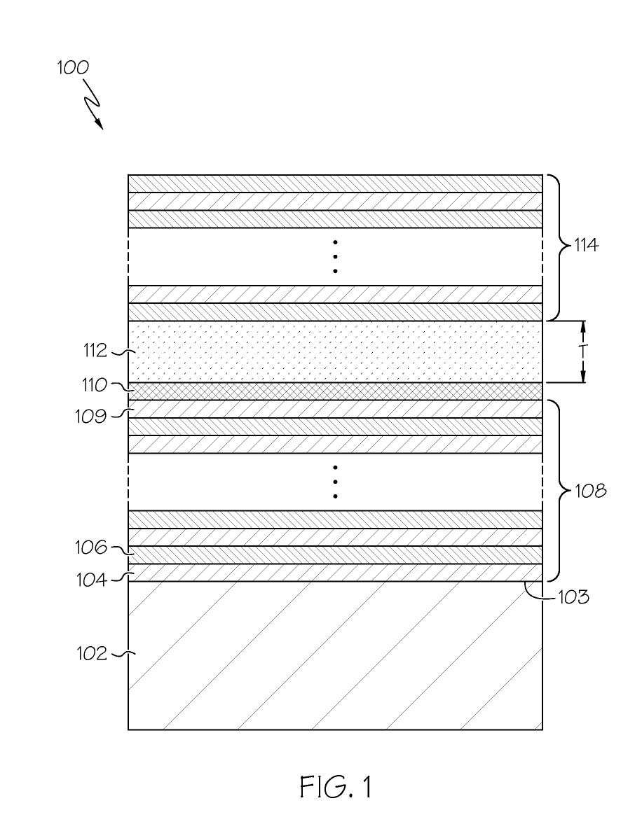

FIG. 1 shows a structure 100 in accordance with an embodiment of the present invention. Structure 100 comprises a substrate 102. Substrate 102 has planar top surface 103. Substrate 102 may comprise silicon, quartz, or a low thermal expansion material (LTEM), and may be in the form of a silicon wafer. Disposed on substrate 102 is a first multilayer region 108. The first multilayer region 108 is comprised of an alternating pattern of a first sub-layer 104 and a second sub-layer 106. In some embodiments, first sub-layer 104 is comprised of silicon and second sub-layer 106 is comprised of molybdenum (Mo). In another embodiment, the second sub-layer 106 is comprised of beryllium (Be). In other embodiments, the first sub-layer may be comprised of lanthanum (La) or a lanthanum-containing compound. The second sub-layer may include boron. Possible first and second sub-layer combinations may include, but are not limited to, LaN/B or La/B₄C or LaN/B or LaN/B₄C. The lanthanum embodiments may be well-suited for EUV energies in the 6 nanometer wavelength range. First sub-layer 104 and second sub-layer 106 together comprise a sub-layer pair. The number and thickness of multilayer region will be dependent upon the choice of materials used in the multilayer region, and may be based on Bragg's equation (n*wavelength=2*distance*sin(theta). In some embodiments, the first multilayer region 108 is comprised of between 30 and 200 sub-layer pairs. For example, in one embodiment, 40.5 pairs are used. When the total number of sub-layers is odd, (as in the case of 40.5 sub-layer pairs), the top sub-layer 109 is comprised of the same material as the first sub-layer 104. In some embodiments, the first sub-layer 104 is comprised of thickness varying from 2 nanometers to 20 nanometers. In one embodiment the first sub-layer 104 is comprised of an about 4 nanometer thick layer of silicon, and the second sub-layer 106 is comprised of an about 3 nanometer thick layer of molybdenum, giving total thickness of about 7 nanometers. In another embodiment, the first sub-layer 104 is comprised of an about 4.16 nanometers thick layer of silicon, and the second sub-layer 106 is comprised of an about 2.77 nanometers thick layer of molybdenum.

A protective layer 110 is disposed on the first multilayer region 108. The protective layer 110 may be comprised of ruthenium (Ru). Ruthenium has good protective properties and also serves as an etch stop layer. In some embodiments, the protective layer has a thickness ranging from about 2.5 nanometers to about 30 nanometers. Protective layer 110 may be deposited by chemical vapor deposition (CVD), ion beam deposition, physical vapor deposition process, sputtering process, atomic layer deposition (ALD), or other suitable method.

Disposed on protective layer 110 is spacer layer 112. In some embodiments, the spacer layer 112 is comprised of silicon. In other embodiments, spacer layer 112 is comprised of carbon. In other embodiments, spacer layer 112 is comprised of boron carbide (B₄C). In other embodiments, spacer layer 112 is comprised of zirconium (Zr). In some embodiments, the spacer layer 112 has a thickness T ranging from about 2 nanometers to about 10 nanometers. Disposed on spacer layer 112 is a second multilayer region 114. In some embodiments, the second multilayer region is comprised of sub-layers of the same types as the first multilayer region 108, such as alternating sub-layers of silicon and molybdenum. Optionally, a capping layer (not shown) may be deposited over the second multilayer region 114. In some embodiments, the second multilayer region 114 is comprised of between 10 and 20 sub-layer pairs. In one embodiment, 14 pairs are used.

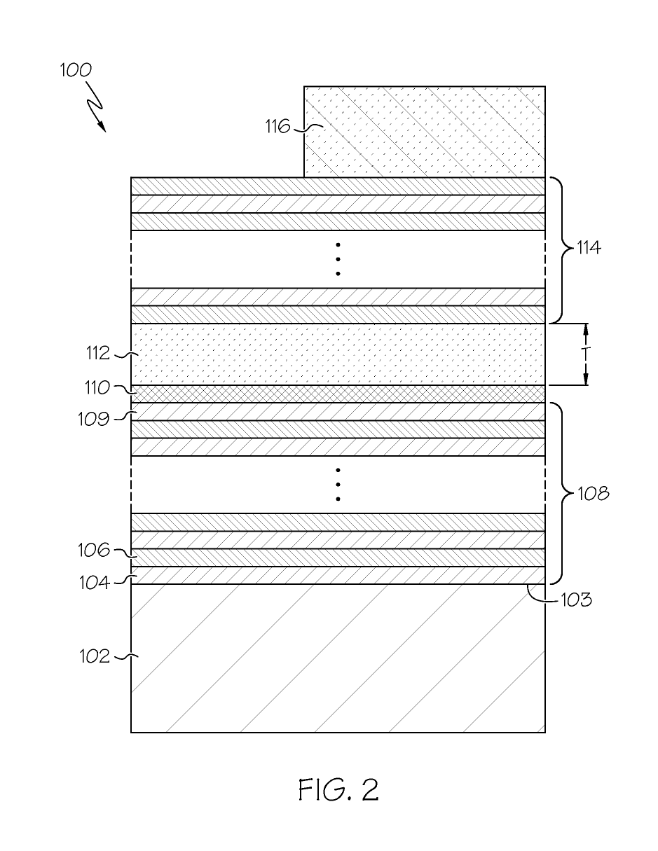

FIG. 2 shows structure 100 after applying a mask 116 using standard patterning techniques. Mask 116 may be comprised of photoresist.

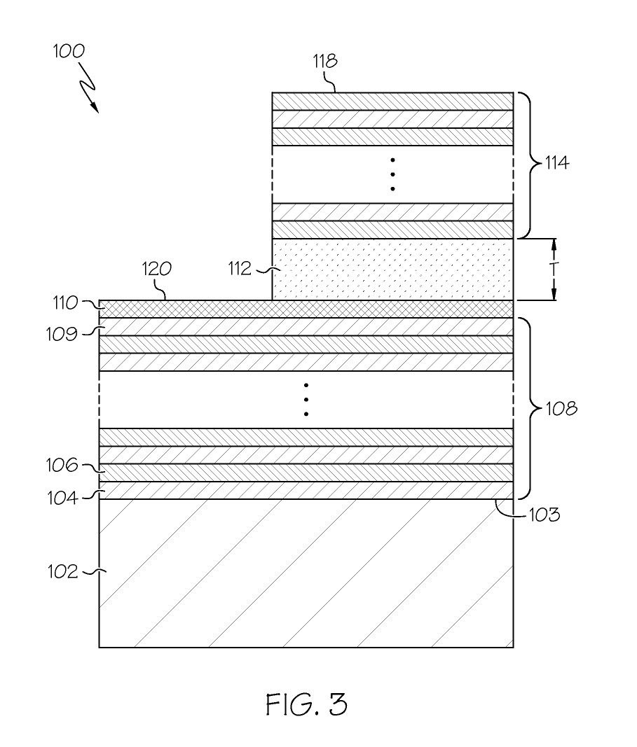

FIG. 3 shows structure 100 after performing an etch and then removing the mask (compare with 116 of FIG. 2). The etch process is directional, and may be a reactive ion etch (RIE) process. The etch process is selective such that it does not etch the protective layer 110. There are two top surfaces for structure 100. Top surface 118 is the top surface of the second multilayer region 114. Top surface 120 is the top surface where the second multilayer region was removed (compare with FIG. 2). The two top surfaces induce different phase shifts. In some embodiments, the phase shift difference between EUV energy reflected from surface 118 compared with surface 120 is about 180 degrees. The spacer layer 112 acts as a Fabry-Perot cavity, and its phase shift difference within the mask is a function of spacer layer thickness. Phase shift can be tuned based on choice of spacer layer thickness for desired applications such as aberration monitor and/or focus monitor for semiconductor lithography systems. For example, in some embodiments, a spacer layer 112 having a thickness T of 4 nanometers results in a phase shift difference of about 90 degrees, a spacer layer 112 having a thickness T of 5 nanometers results in a phase shift difference of about 135 degrees, and a spacer layer 112 having a thickness T of 6 nanometers results in a phase shift difference of about 180 degrees. No absorber is used with the structure of FIG. 3, and, hence, alignment issues associated with patterning such an absorber on a phase shift mask are eliminated.

Embodiments of the present invention therefore have a first phase corresponding to the top surface 118 and a second phase corresponding to top surface 120. Furthermore, top surface 118 has a first reflectance value and top surface 120 has a second reflectance value. In some embodiments, the first reflectance value and second reflectance value may be similar. In other embodiments, the first reflectance value and second reflectance value may be different. The amount of sub-layers within the multilayers is a parameter that can be adjusted to achieve different reflectance values. The difference in phase shift is achieved via the Fabry-Perot cavity formed by spacer layer 112 and the difference in height between the two top surfaces, which is controllable via a selective etch process. As a result, the transition area between the top surface 118 and the top surface 120 is greatly reduced compared with prior art processes for fabricating phase shift masks. Another advantage for this design is that the phase shift and reflectivity from top surface 118 and 120 can be tuned simultaneously with Fabry-Perot cavity 112.

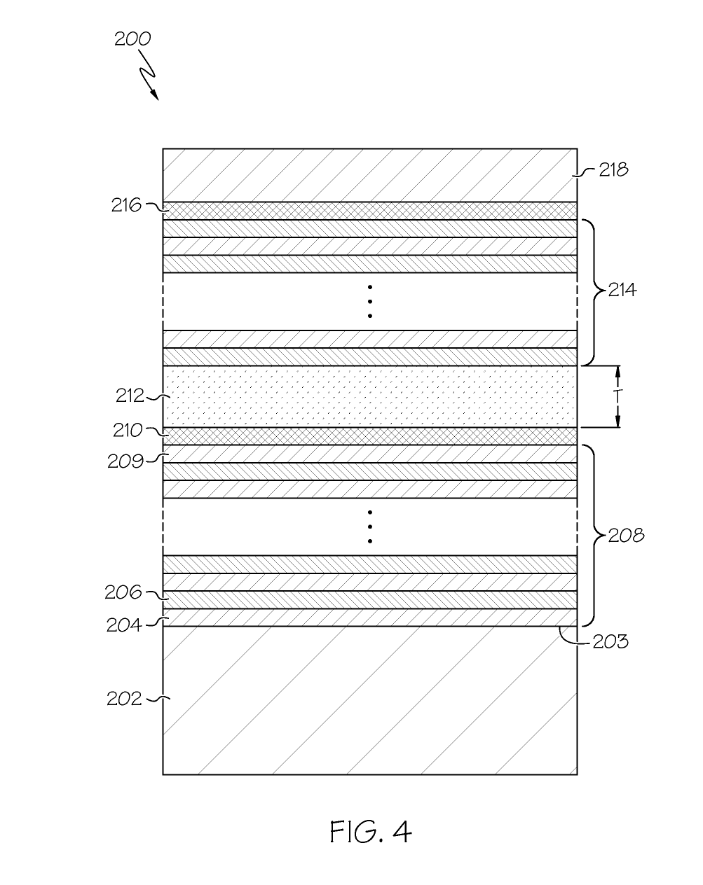

FIG. 4 shows a structure 200 in accordance with an alternative embodiment of the present invention. Structure 200 has some similarity to structure 100 of FIG. 1. Structure 200 comprises a substrate 202. Substrate 202 has planar top surface 203. Substrate 202 may comprise silicon and may be in the form of a silicon wafer. Other possible materials for substrate 202 include quartz, or a LTEM. Disposed on substrate 202 is a first multilayer region 208. The first multilayer region 208 is comprised of an alternating pattern of a first sub-layer 204 and a second sub-layer 206. First sub-layer 204 and second sub-layer 206 together comprise a sub-layer pair. In some embodiments, first sub-layer 204 is comprised of silicon and second sub-layer 206 is comprised of molybdenum (Mo). In another embodiment, the second sub-layer 206 is comprised of beryllium (Be). In other embodiments, the first sub-layer may be comprised of lanthanum (La) or a lanthanum-containing compound. The second sub-layer may include boron. Possible first and second sub-layer combinations may include, but are not limited to, LaN/B or La/B₄C or LaN/B or LaN/B₄C. The lanthanum embodiments may be well-suited for EUV energies in the 6 nanometer wavelength range. In some embodiments, the first multilayer region 208 is comprised of between 40 and 60 sub-layer pairs. In one embodiment, 50 pairs are used. In some embodiments, the first sub-layer 204 is comprised of a 4 nanometer thick layer of silicon, and the second sub-layer 206 is comprised of a 3 nanometer thick layer of molybdenum. In another embodiment, the first sub-layer 204 is comprised of a 4.16 nanometers thick layer of silicon, and the second sub-layer 206 is comprised of a 2.77 nanometers thick layer of molybdenum.

A first protective layer 210 is disposed on the first multilayer region 208. The first protective layer 210 may be comprised of ruthenium (Ru). In some embodiments, the first protective layer has a thickness ranging from about 2.5 nanometers to about 30 nanometers. First protective layer 210 may be deposited by chemical vapor deposition (CVD), atomic layer deposition (ALD), ion beam deposition, physical vapor deposition process, sputtering process, or other suitable method.

Disposed on first protective layer 210 is spacer layer 212. In some embodiments, the spacer layer 212 is comprised of silicon. In other embodiments, spacer layer 212 is comprised of carbon. In other embodiments, spacer layer 212 is comprised of boron carbide (B₄C). In other embodiments, spacer layer 212 is comprised of zirconium (Zr). In some embodiments, the spacer layer 212 has a thickness T ranging from about 2 nanometers to about 10 nanometers. Disposed on spacer layer 212 is a second multilayer region 214. In some embodiments, the second multilayer region 214 is comprised of sub-layers of the same types as the first multilayer region 208, such as alternating sub-layers of silicon and molybdenum. In some embodiments, the second multilayer region 214 is comprised of between 10 and 20 sub-layer pairs. In one embodiment, 14 pairs are used.

Disposed on the second multilayer region 214 is a second protective layer 216. The second protective layer 216 may be similar to first protective layer 210, and may also be comprised of ruthenium.

Disposed on the second protective layer 216 is an absorber layer 218. In some embodiments, the absorber layer 218 is comprised of materials that absorb EUV light, including, but not limited to TaN, TaON, TaBN, TaTe₂O₇, Ni, or Cr. Other absorber materials are possible. In some embodiments, the thickness of absorber layer 218 ranges from about 10 nanometers to about 100 nanometers. In other embodiments, the thickness of absorber layer 218 ranges from about 30 nanometers to about 70 nanometers. In a particular embodiment, the absorber layer 218 is 58 nanometers.

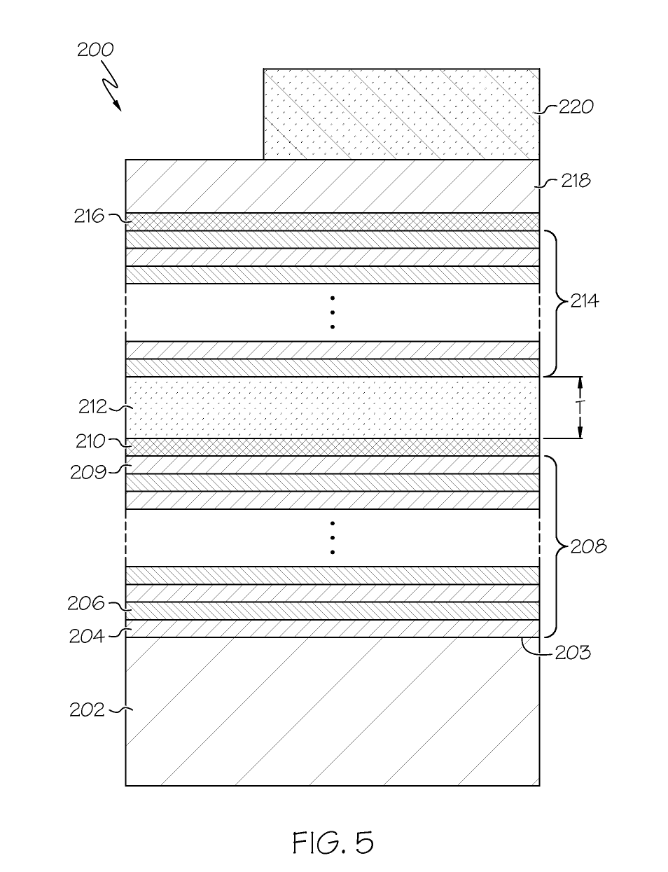

FIG. 5 shows structure 200 after applying a mask 220 using standard patterning techniques. Mask 220 may be comprised of photoresist.

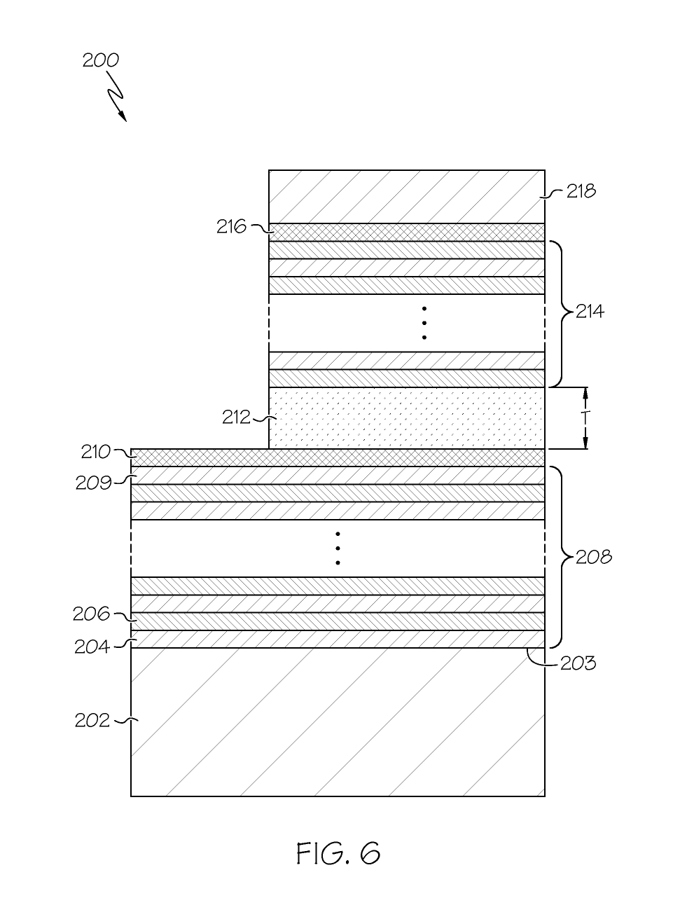

FIG. 6 shows structure 200 after performing an etch and then removing the mask (compare with 220 of FIG. 5). The etch process is directional, and may be a reactive ion etch (RIE) process. The etch process is selective such that it does not etch the first protective layer 210.

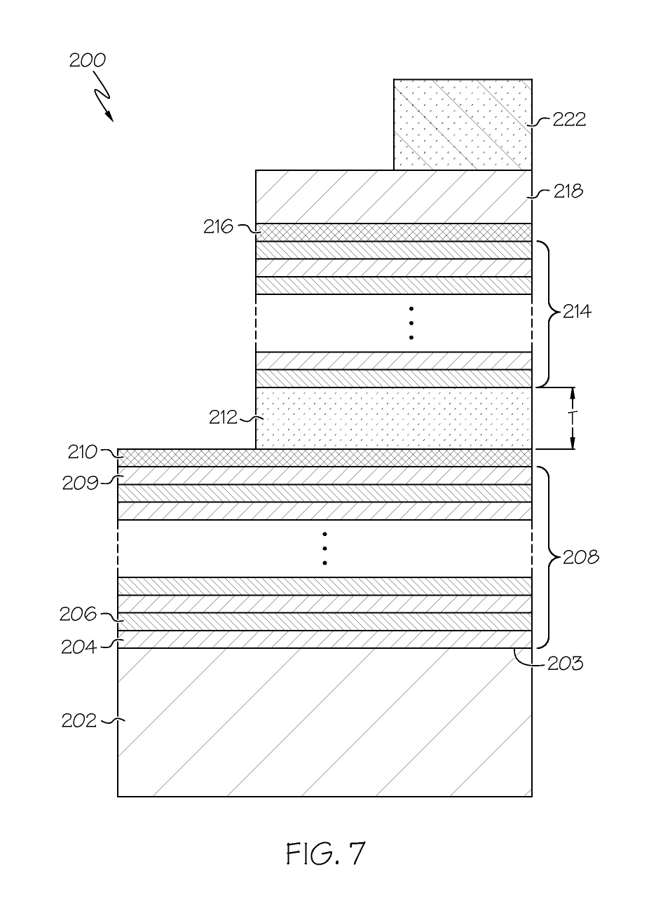

FIG. 7 shows structure 200 after applying a second mask 222 using standard patterning techniques. Mask 222 may be comprised of photoresist. Mask 222 covers a smaller area than the remaining absorber layer 218.

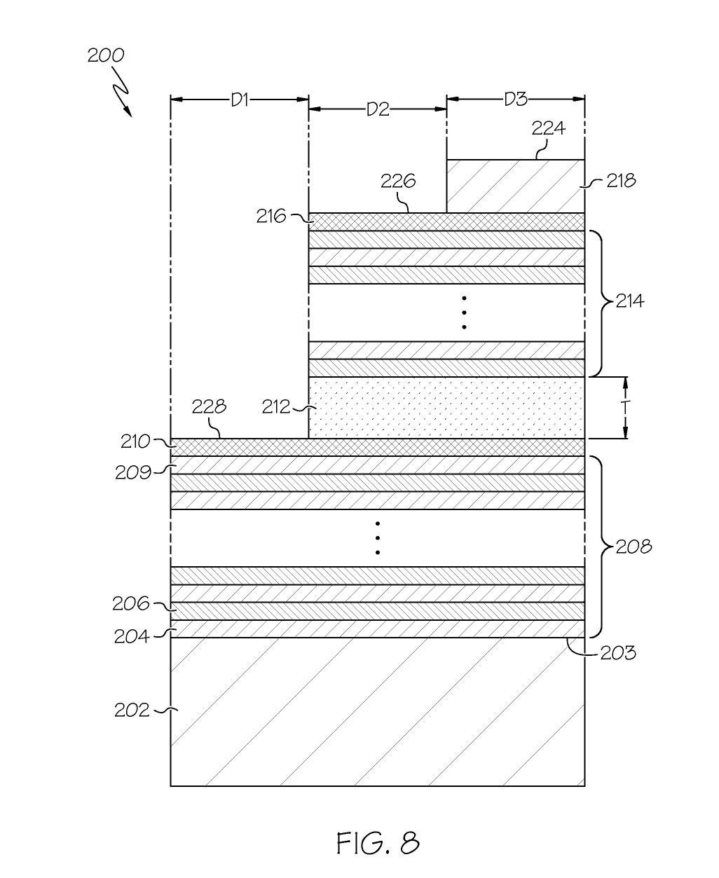

FIG. 8 shows structure 200 after performing a second etch to remove a portion of the absorber layer 218, and then removing the second mask (compare with 222 of FIG. 7). There are three top surfaces for structure 200. Top surface 224 is the top surface of absorber layer 218. Its reflectance value is essentially zero. Top surface 226 is the top surface of the second protective layer 216, which is disposed on the second multilayer 214 and the spacer layer 212. Top surface 228 is the top surface of the first protective layer 210, which is disposed on the first multilayer 208. Top surface 228 provides a first reflectance value and a first phase shift value. Top surface 226 provides a second reflectance value and a second phase shift value. In some embodiments, the first reflectance value and the second reflectance value are similar, and the difference between the first phase shift value and the second phase shift value is about 90 degrees. Top surface 228 has a distance D1, top surface 226 has a distance D2, and top surface 224 has a distance D3. In some embodiments, D1, D2, and D3 are equal, and may range from about 5 nanometers to about 20 nanometers but can be used for features greater than 20 nanometers. Structure 200 is well suited for focus monitoring applications.

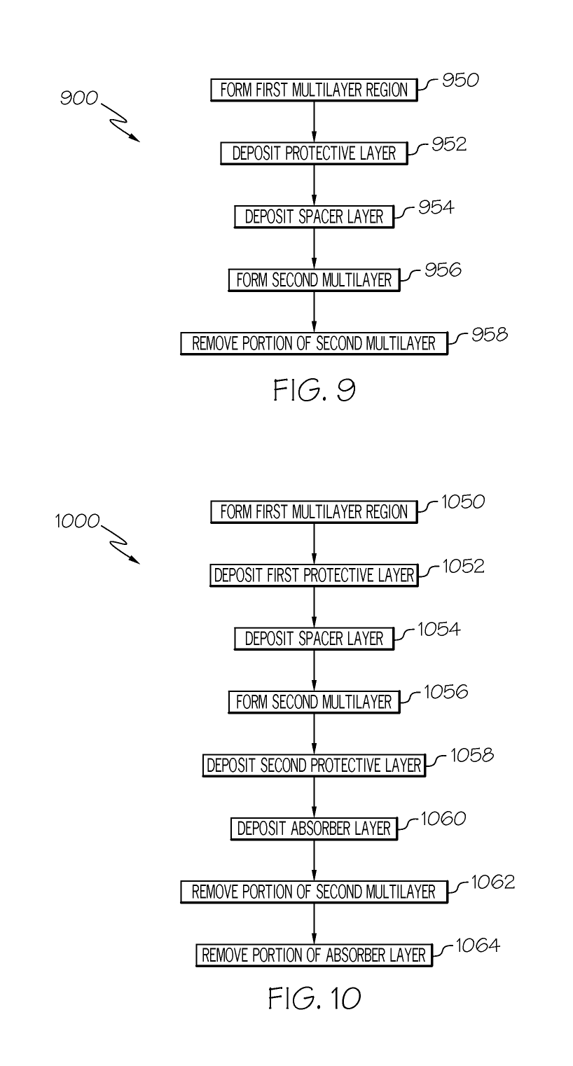

FIG. 9 is a flowchart 900 showing process steps for embodiments of the present invention. In process step 950, a first multilayer region is formed (see 108 of FIG. 1). In process step 952, a protective layer is deposited (see 110 of FIG. 1). In process step 954, a spacer layer is formed (see 112 of FIG. 1). In process step 956, a second multilayer region is formed (see 114 of FIG. 1). In process step 958, a portion of the second multilayer region is removed (see 120 of FIG. 3).

FIG. 10 is a flowchart 1000 showing process steps for alternative embodiments of the present invention. In process step 1050, a first multilayer region is formed (see 208 of FIG. 4). In process step 1052, a first protective layer is deposited (see 210 of FIG. 4). In process step 1054, a spacer layer is formed (see 212 of FIG. 4). In process step 1056, a second multilayer region is formed (see 214 of FIG. 1). In process step 1058, a second protective layer is deposited (see 216 of FIG. 1). In process step 1060, an absorber layer is deposited (see 218 of FIG. 1). In process step 1062, a portion of the second multilayer region is removed (see FIG. 6). In process step 1064, a portion of the absorber layer is removed (see FIG. 8).

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A phase shift mask, comprising:
a substrate;
a first multilayer region disposed on the substrate;
a protective layer disposed on the first multilayer region;
a spacer layer disposed on a first portion of the protective layer; and
a second multilayer region disposed on the spacer layer, wherein a second portion of the protective layer is exposed.

2. The phase shift mask of claim 1, wherein the protective layer is comprised of ruthenium.

3. The phase shift mask of claim 1, wherein the first multilayer region is comprised of alternating sub-layers of silicon and molybdenum.

4. The phase shift mask of claim 3, wherein the first multilayer region comprises between 30 and 200 sub-layer pairs.

5. The phase shift mask of claim 1, wherein the first multilayer region is comprised of alternating sub-layers comprised of lanthanum and boron.

6. The phase shift mask of claim 1, wherein the spacer layer is comprised of silicon.

7. The phase shift mask of claim 1, wherein the spacer layer is comprised of carbon.

8. The phase shift mask of claim 1, wherein the first multilayer region has a first phase shift, and wherein the second multilayer region has a second phase shift, wherein the first phase shift is approximately 180 degrees from the second phase shift.

9. The phase shift mask of claim 6, wherein the spacer layer has a thickness ranging from about 2 nanometers to about 50 nanometers.

10. The phase shift mask of claim 5, wherein the second multilayer region is comprised of alternating sub-layers of silicon and molybdenum and comprises between 5 and 200 sub-layer pairs.

11. A phase shift mask, comprising:
a substrate;
a first multilayer region disposed on the substrate;
a first protective layer disposed on the first multilayer region;
a spacer layer disposed on a first portion of the first protective layer;
a second multilayer region disposed on the spacer layer, wherein a second portion of the first protective layer is exposed;
a second protective layer disposed on the second multilayer region; and
an absorber layer disposed on a first portion of the second protective layer, wherein a second portion of the second protective layer is exposed.

12. The phase shift mask of claim 11, wherein the first protective layer and the second protective layer are comprised of ruthenium.

13. The phase shift mask of claim 12, wherein the first multilayer region and the second multilayer region are comprised of alternating sub-layers of silicon and molybdenum.

14. The phase shift mask of claim 13, wherein the spacer layer is comprised of silicon.

15. The phase shift mask of claim 14, wherein the first multilayer region has a first phase shift, and wherein the second multilayer region has a second phase shift, wherein the first phase shift is approximately 90 degrees from the second phase shift.

16. The phase shift mask of claim 15, wherein the absorber layer has a thickness ranging from about 20 nanometers to about 70 nanometers.

17. A method of fabricating a phase shift mask, comprising:
forming a first multilayer region on a substrate;
depositing a first protective layer on the first multilayer region;
depositing a spacer layer on the first protective layer;
forming a second multilayer region on the spacer layer; and
removing a portion of the second multilayer region and spacer region.

18. The method of claim 17, wherein depositing a first protective layer comprises depositing ruthenium.

19. The method of claim 18, wherein depositing a spacer layer comprises depositing silicon.

20. The method of claim 17, further comprising:
depositing a second protective layer on the second multilayer region;
depositing an absorber layer on the second multilayer region; and
removing a portion of the absorber layer.
